(19) United States
(12) Patent Application Publication
(10) Pub. No.: US 2020/0161171 A1
(43) Pub. Date: May 21, 2020

(54) SCALED LINER LAYER FOR ISOLATION STRUCTURE

(71) Applicant: Applied Materials, Inc., Santa Clara, CA (US)

(72) Inventors: Benjamin COLOMBEAU, Salem, MA (US); Theresa Kramer GUARINI, San Jose, CA (US); Malcolm BEVAN, Santa Clara, CA (US); Rui CHENG, Santa Clara, CA (US)

(21) Appl. No.: 16/579,759

(22) Filed: Sep. 23, 2019

Related U.S. Application Data
(60) Provisional application No. 62/768,569, filed on Nov. 16, 2018.

(51) Int. Cl. H01L 21/762; H01L 21/02; H01J 37/32; C23C 16/56; C23C 16/24; C23C 16/28; C23C 16/50

(52) U.S. Cl. CPC H01L 21/76227; H01L 21/02247; H01L 21/02252; H01J 37/32743; H01J 37/32788; H01J 2237/332; C23C 16/56; C23C 16/24; C23C 16/28; C23C 16/50; H01J 37/32816

(57) ABSTRACT

Generally, examples described herein relate to methods and processing systems for forming isolation structures (e.g., shallow trench isolations (STIs)) between fins on a substrate. In an example, fins are formed on a substrate. A liner layer is conformally formed on and between the fins. Forming the liner layer includes conformally depositing a pre-liner layer on and between the fins, and densifying, using a plasma treatment, the pre-liner layer to form the liner layer. A dielectric material is formed on the liner layer.

### CROSS-REFERENCE TO RELATED APPLICATIONS

This application claims priority to and the benefit of U.S. Provisional Patent Application Ser. No. 62/768,569, filed on Nov. 16, 2018, and entitled “Scaled Liner Layer for Isolation Structure,” which is incorporated herein by reference in its entirety.

### BACKGROUND

### Field

Examples described herein generally relate to the field of semiconductor processing, and more specifically, to scaling a liner layer for an isolation structure for a semiconductor device.

### Description of the Related Art

Reliably producing nanometer and smaller features is one of the key technology challenges for next generation very large scale integration (VLSI) and ultra large-scale integration (ULSI) of semiconductor devices. As the limits of circuit technology are pushed, the shrinking dimensions of VLSI and ULSI technology have placed additional demands on processing capabilities. As the dimensions of the integrated circuit components are reduced (e.g., in nanometer dimensions), the materials and processes used to fabricate components are generally carefully selected in order to obtain satisfactory levels of electrical performance.

The reduced dimensions of integrated circuit components can lead to increasingly smaller gaps between components. Some processes that may have been suitable for filling similar gaps at larger dimensions may not be suitable to fill gaps at the smaller dimensions. Therefore, there is need for a process and processing system that is able to form complex devices at smaller dimensions while maintaining satisfactory performance of the devices of the integrated circuit.

Even further, due to the complexity of VLSI and ULSI structures today, substrates on which these devices are formed must be processed in multiple different processing chambers that are configured to typically perform at least one of a patterning step, a deposition step, an etching step, or a thermal processing step. Due to incompatibility between process chemistries, difference in chamber throughput, or processing technology, it is common in the semiconductor fabrication industry for equipment manufacturers to position only certain types of processing technology (e.g., deposition chambers) in one processing system and another processing technology (e.g., etching chambers) in another processing system. The division of the processing technologies, found in conventional semiconductor equipment, requires the substrates to be transferred from one processing system to another so that the various different semiconductor manufacturing processes can be performed on a substrate. The transferring process performed between the various processing systems exposes the substrates to various forms of contamination and particles. Therefore, there is need for a process and processing equipment that is able to form complex devices and that avoids the common contamination and particle sources that effect semiconductor processing today.

### SUMMARY

Embodiments of the disclosure include a method for semiconductor processing. Fins are formed on a substrate. A liner layer is conformally formed on and between the fins. Forming the liner layer includes conformally depositing a pre-liner layer on and between the fins, and densifying, using a plasma treatment, the pre-liner layer to form the liner layer. A dielectric material is formed on the liner layer.

Embodiments of the disclosure also include a semiconductor processing system. The semiconductor processing system includes a transfer apparatus, a first processing chamber coupled to the transfer apparatus, a second processing chamber coupled to the transfer apparatus, and a system controller. The system controller is configured to control a deposition process performed in the first processing chamber, control a transfer of the substrate from the first processing chamber to the second processing chamber through the transfer apparatus, and control a plasma treatment process performed in the second processing chamber. The deposition process conformally deposits a pre-liner layer on and between fins on a substrate. The plasma treatment process densifies the pre-liner layer to form a liner layer.

Embodiments of the disclosure further include a semiconductor processing system that includes a non-transitory computer-readable medium storing instructions that, when executed by a processor, cause a computer system to perform operations. The operations include controlling a deposition process in a first processing chamber of a processing system, controlling a transfer of the substrate from the first processing chamber to a second processing chamber of the processing system through a transfer apparatus of the processing system, and controlling a plasma treatment process in the second processing chamber. The deposition process conformally deposits a pre-liner layer on and between fins on a substrate. The first processing chamber and the second processing chamber are coupled to the transfer apparatus. The plasma treatment process densifies the pre-liner layer to form a liner layer.

### BRIEF DESCRIPTION OF THE DRAWINGS

So that the manner in which the above recited features of the present disclosure can be understood in detail, a more particular description, briefly summarized above, may be had by reference to examples, some of which are illustrated in the appended drawings. It is to be noted, however, that the appended drawings illustrate only some examples and are therefore not to be considered limiting of the scope of this disclosure, for the disclosure may admit to other equally effective examples.

FIG. 1 is a schematic top-view diagram of an example multi-chamber processing system according to some examples of the present disclosure.

FIG. 2 is a cross-sectional view of a processing chamber that may be used to perform a cleaning process according to some examples of the present disclosure.

FIG. 3 is a cross-sectional view of a processing chamber that may be used to perform a deposition process according to some examples of the present disclosure.

FIG. 4 is a cross-sectional view of a processing chamber that may be used to perform a plasma treatment according to some examples of the present disclosure.

FIG. 5 is a flowchart of a method of semiconductor processing according to some examples of the present disclosure.

FIGS. 6 through 10 are cross-sectional views of intermediate semiconductor structures illustrating aspects of the method of FIG. 5 according to some examples of the present disclosure.

To facilitate understanding, identical reference numerals have been used, wherever possible, to designate identical elements that are common to the figures.

### DETAILED DESCRIPTION

Generally, examples described herein relate to methods and processing systems for forming isolation structures (e.g., shallow trench isolations (STIs)) between fins on a substrate. The isolation structures formed by such processing can be implemented in, for example, fin field-effect-transistors (FinFETs). The methods and processing systems can provide an isolation structure having a highly conformal, hermetic liner layer that can reduce oxidation of fins, which can further reduce loss of widths (e.g., a critical dimension (CD)) of the fins as a result of processing. The liner layer can be formed in trenches between fins where a distance between fins is small. Additionally, the liner layer can be formed using low temperature (e.g., equal to or less than 550° C.) processing, which can reduce stress and bending of the fins. The liner layer can be formed without using a chlorine-containing gas, which can reduce safety and environmental concerns, and can permit flexibility in subsequent processing. Additionally, the formation of the liner layer can be by using an integrated processing solution.

Due to the continued scaling of semiconductor devices, formation of isolation structures between fins has become increasingly challenging. Techniques for forming a liner layer for an isolation structure have not been able to form a liner layer with sufficient step coverage, which prevents the liner layer from being hermetic. If the liner layer is not hermetic, a fin on which the liner layer is formed can oxidize, which can subsequently result in a loss of width of the fin during recessing of the isolation structures. Additionally, the thermal budget for forming such a liner layer can be too high, which can result in the creation of stress in the isolation structures, which can in turn cause bending in fins.

Examples described herein can provide for a highly conformal, hermetic liner layer that is capable of reducing or preventing oxidation of the fin, which can reduce loss of fin width. The liner layer can be formed using low temperature processing, which can reduce stress and fin bending. Systems and methods described herein can provide for an integrated solution to forming the liner layer such that the substrate on which the liner layer is formed is not exposed to an atmospheric ambient environment (e.g., an environment in a fabrication facility (a “fab”)) between various processes implemented to form the liner layer. By avoiding exposure to an atmospheric ambient environment, a cleaning step between the various processes implemented to form the liner layer can be avoided. Other benefits of various examples are described herein; while a person having ordinary skill in the art will readily understand other advantages and benefits of examples within the scope of this disclosure.

Various different examples are described below. Although multiple features of different examples may be described together in a process flow or system, the multiple features can each be implemented separately or individually and/or in a different process flow or different system. Additionally, various process flows are described as being performed in an order; other examples can implement process flows in different orders and/or with more or fewer operations.

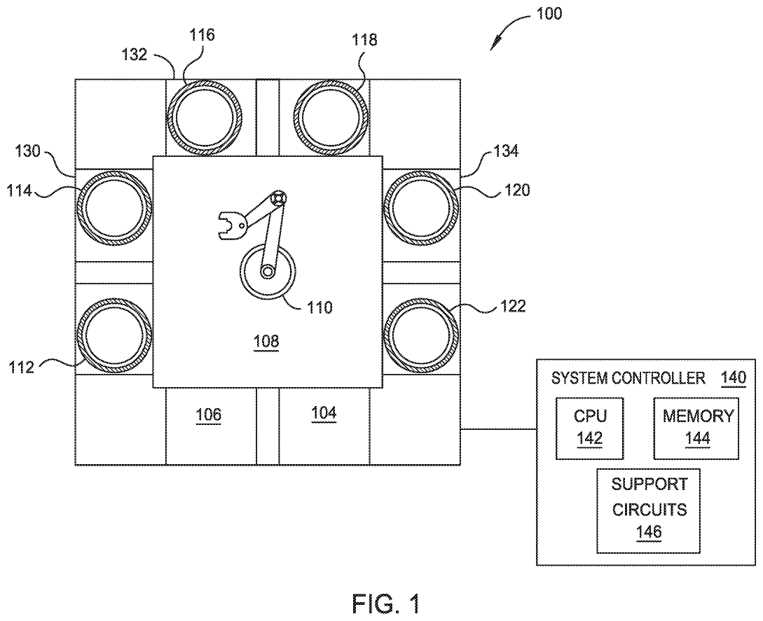

FIG. 1 is a schematic top-view diagram of a multi-chamber processing system 100 according to some examples of the present disclosure. The processing system 100 generally includes load lock chambers 104, 106, transfer chamber 108 with a transfer robot 110, and processing chambers 112, 114, 116, 118, 120, 122. The processing system 100 can further include a factory interface (not shown). As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be transferred between the various chambers in a low pressure (e.g., less than or equal to about 300 Torr) or vacuum environment without breaking the low pressure or vacuum environment between various processes performed on the substrates in the processing system 100. Accordingly, the processing system 100 may provide for an integrated solution for some processing of substrates.

Examples of a processing system that may be suitably modified in accordance with the teachings provided herein include the Producer® or other suitable processing systems commercially available from Applied Materials, Inc., located in Santa Clara, Calif. It is contemplated that other processing systems (including those from other manufacturers) may be adapted to benefit from aspects described herein.

As illustrated, processing chambers 112, 114 are grouped in a tandem unit 130; processing chambers 116, 118 are grouped in a tandem unit 132; and processing chambers 120, 122 are grouped in a tandem unit 134. Tandem units 130, 132, 134 each may have a respective single supply of process gases. The tandem units 130, 132, 134 are positioned around the transfer chamber 108. The processing chambers 112, 114, 116, 118, 120, 122 are coupled to the transfer chamber 108, e.g., via respective ports therebetween. Similarly, the load lock chambers 104, 106 are coupled to the transfer chamber 108, e.g., via respective ports therebetween. The transfer chamber 108 has a transfer robot 110 for handling and transferring substrates between chambers. A factory interface may be coupled to the load lock chambers 104, 106 (e.g., with the load lock chambers 104, 106 disposed between the factory interface and the transfer chamber 108) in some examples.

The load lock chambers 104, 106 have respective ports coupled to the transfer chamber 108. The transfer chamber 108 further has respective ports coupled to processing chambers 112, 114, 116, 118, 120, 122. The ports can be, for example, slit valve openings with slit valves for passing substrates therethrough by the transfer robot 110 and for providing a seal between respective chambers to prevent a gas from passing between the respective chambers. Generally, any port is open for transferring a substrate therethrough; otherwise, the port is closed.

The load lock chambers 104, 106, transfer chamber 108, and processing chambers 112, 114, 116, 118, 120, 122 may be fluidly coupled to a gas and pressure control system (not specifically illustrated). The gas and pressure control system can include one or more gas pumps (e.g., turbo pumps, cryo-pumps, roughing pumps, etc.), gas sources, various valves, and conduits fluidly coupled to the various chambers. In operation, a substrate is transferred to a load lock chamber 104 or 106 (e.g., from a factory interface). The gas and pressure control system then pumps down the load lock chamber 104 or 106. The gas and pressure control system further maintains the transfer chamber 108 with an interior low pressure or vacuum environment (which may include an inert gas). Hence, the pumping down of the load lock chamber 104 or 106 facilitates passing the substrate between, e.g., the atmospheric environment of a factory interface and the low pressure or vacuum environment of the transfer chamber 108.

With the substrate in the load lock chamber 104 or 106 that has been pumped down, the transfer robot 110 transfers the substrate from the load lock chamber 104 or 106 into the transfer chamber 108 through the respective port coupling the load lock chamber 104 or 106 to the transfer chamber 108. The transfer robot 110 is then capable of transferring the substrate to and/or between any of the processing chambers 112, 114, 116, 118, 120, 122 through the respective ports for processing. The transfer of the substrate within and among the various chambers can be in the low pressure or vacuum environment provided by the gas and pressure control system.

The processing chambers 112, 114, 116, 118, 120, 122 can be any appropriate chamber for target processing. In some examples, the processing chamber 112 can be capable of performing a cleaning process; the processing chamber 116 can be capable of performing a deposition process (e.g., plasma enhanced CVD or thermal CVD process); and the processing chamber 120 can be capable of performing a plasma process and/or thermal process. These processing chambers 112, 116, 120 are identified for ease of subsequent description. Other processing chambers can perform these processes. The processing chamber 112 may be a SiCoNi® Preclean chamber available from Applied Materials of Santa Clara, Calif. The processing chamber 116 may be a Precision® chamber available from Applied Materials of Santa Clara, Calif. The processing chamber 120 may be a DPX™ chamber available from Applied Materials of Santa Clara, Calif. Other chambers available from other manufacturers may be implemented.

A system controller 140 is coupled to the processing system 100 for controlling the processing system 100 or components thereof. For example, the system controller 140 may control the operation of the processing system 100 using a direct control of the chambers 104, 106, 108, 112, 114, 116, 118, 120, 122 of the processing system 100 or by controlling controllers associated with the chambers 104, 106, 108, 112, 114, 116, 118, 120, 122. In operation, the system controller 140 enables data collection and feedback from the respective chambers to coordinate performance of the processing system 100.

The system controller 140 generally includes a central processing unit (CPU) 142, memory 144, and support circuits 146. The CPU 142 may be one of any form of a general purpose processor that can be used in an industrial setting. The memory 144, or non-transitory computer-readable medium, is accessible by the CPU 142 and may be one or more of memory such as random access memory (RAM), read only memory (ROM), floppy disk, hard disk, or any other form of digital storage, local or remote. The support circuits 146 are coupled to the CPU 142 and may comprise cache, clock circuits, input/output subsystems, power supplies, and the like. The various methods disclosed herein may generally be implemented under the control of the CPU 142 by the CPU 142 executing computer instruction code stored in the memory 144 (or in memory of a particular processing chamber) as, e.g., a software routine. When the computer instruction code is executed by the CPU 142, the CPU 142 controls the chambers to perform processes in accordance with the various methods.

Other processing systems can be in other configurations. For example, more or fewer processing chambers may be coupled to a transfer apparatus. In the illustrated example, the transfer apparatus includes the transfer chamber 108. In other examples, more transfer chambers (e.g., two or more transfer chambers) and/or one or more holding chambers may be implemented as a transfer apparatus in a processing system.

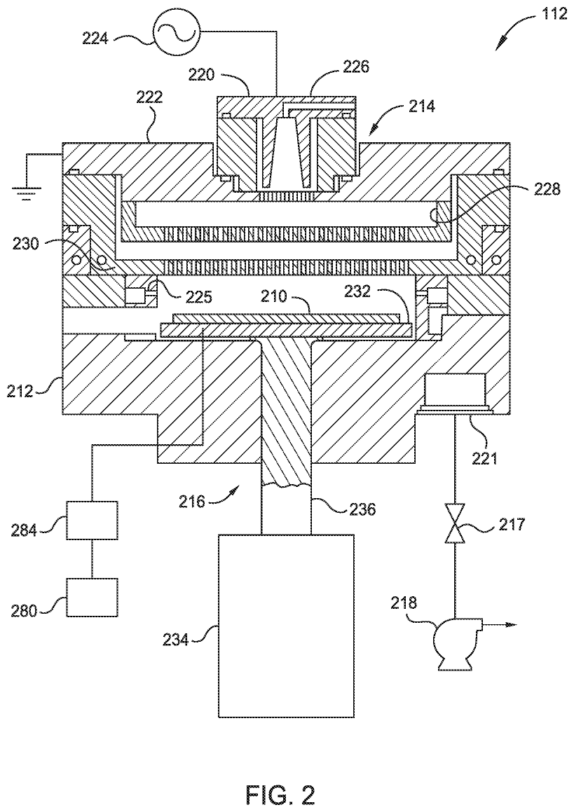

FIG. 2 is a cross-sectional view of a processing chamber 112 that may be used to perform a cleaning process according to some examples of the present disclosure. The processing chamber 112 may be a SiCoNi® Preclean chamber available from Applied Materials of Santa Clara, Calif. The processing chamber 112 includes a chamber body 212, a lid assembly 214, and a substrate support assembly 216. The lid assembly 214 is disposed at an upper end of the chamber body 212, and the substrate support assembly 216 is at least partially disposed within the chamber body 212. The chamber body 212, lid assembly 214, and substrate support assembly 216 together define a region in which a substrate may be processed.

The lid assembly 214 includes at least two stacked components configured to form a plasma region therebetween. A first electrode 220 is disposed vertically above a second electrode 222 confining a plasma volume therebetween. The first electrode 220 is connected to a radio frequency (RF) power source 224, and the second electrode 222 is connected to an electrical ground, which forms a capacitance between the first electrode 220 and the second electrode 222.

The lid assembly 214 also includes one or more gas ports 226 for providing a cleaning gas to a substrate surface through a blocker plate 228 and a gas distribution plate 230, such as a showerhead. The cleaning gas may be an etchant, ionized gas, or active radical, such as ionized fluorine, chlorine, or ammonia. In other examples, a different cleaning process may be utilized to clean the substrate surface. For example, a remote plasma containing helium (He) and nitrogen trifluoride (NF₃) may be introduced into the processing chamber 112 through the gas distribution plate 230, while ammonia (NH₃) may be directly injected into the processing chamber 112 via a separate gas entry port 225 that is disposed at a side of the chamber body 212.

The substrate support assembly 216 may include a substrate support 232 to support a substrate 210 thereon during processing. The substrate support 232 has a flat substrate supporting surface for supporting the substrate to be processed thereon. The substrate support 232 may be coupled to an actuator 234 by a shaft 236 which extends through a centrally-located opening formed in a bottom of the chamber body 212. The actuator 234 may be flexibly sealed to the chamber body 212 by bellows (not shown) that prevent vacuum leakage from around the shaft 236. The actuator 234 allows the substrate support 232 to be moved vertically within the chamber body 212 between a process position and a lower, transfer position. The transfer position is slightly below the opening of a slit valve opening formed in a sidewall of the chamber body 212. In operation, the substrate support 232 may be elevated to a position in close proximity to the lid assembly 214 to control the temperature of the substrate 210 being processed. As such, the substrate 210 may be heated via radiation emitted or convection from the gas distribution plate 230.

A bias power source 280 may be coupled to the substrate support 232 through an impedance matching network 284. The bias power source 280 provides a bias to the substrate 210 to direct the ionized cleaning gas toward the substrate 210.

A vacuum system, which may be part of the gas and pressure control system of the processing system 100, can be used to evacuate gases from the processing chamber 112. The vacuum system includes a vacuum pump 218 coupled, via a valve 217, to a vacuum port 221 disposed in the chamber body 212. The processing chamber 112 also includes a controller (not shown), which may be the system controller 140 or a controller controlled by the system controller 140, for controlling processes within the processing chamber 112.

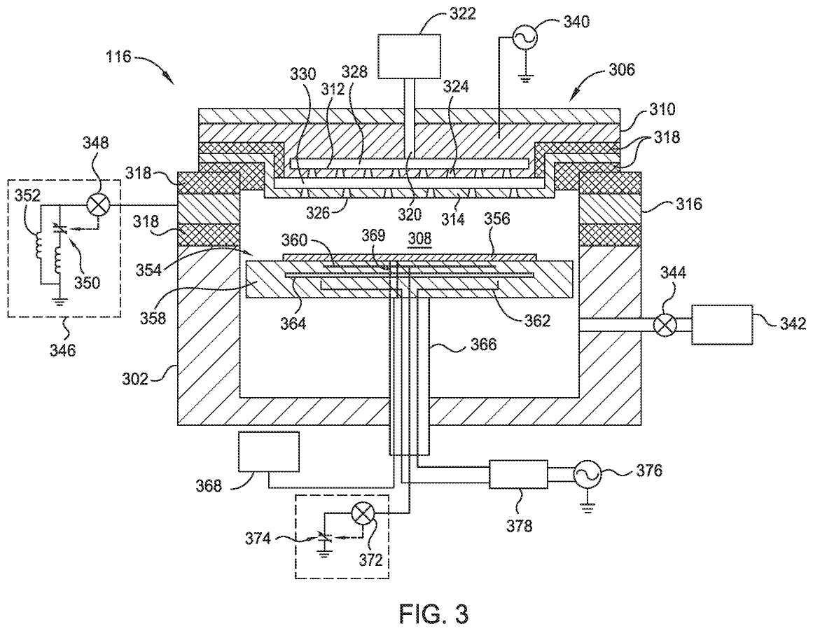

FIG. 3 is a cross-sectional view of the processing chamber 116 that may be used to perform a deposition process according to some examples of the present disclosure. The processing chamber 116 is a chamber for deposition of a thin film or layer on a substrate. As described here, the processing chamber 116 is configured to implement a plasma-enhanced chemical vapor deposition (PECVD), although other examples contemplate that the processing chamber 116 is configured to implement other types of deposition processes, such as CVD (more broadly), atomic layer deposition (ALD), or another deposition process. The processing chamber 112 may be a Precision® chamber available from Applied Materials of Santa Clara, Calif.

The processing chamber 116 includes a chamber body 302, a lid assembly 306, and a substrate support assembly 354. The lid assembly 306 is disposed at an upper end of and is supported by the chamber body 302, and the substrate support assembly 354 is at least partially disposed within the chamber body 302. The chamber body 302, lid assembly 306, and substrate support assembly 354 together define an interior processing region 308 within the processing chamber 116 in which a substrate may be processed. The interior processing region 308 may be accessed through a port (not shown) formed in the chamber body 302 that facilitates transfer of a substrate into and out of the processing chamber 116. The chamber body 302 may be fabricated from a unitary block of aluminum or other material compatible with processing.

The lid assembly 306 includes a base plate 310, a blocker plate 312, a gas distribution plate 314, a modulation electrode 316, and insulators 318. The base plate 310, blocker plate 312 and gas distribution plate 314 may be fabricated from stainless steel, aluminum, anodized aluminum, nickel, or any other RF conductive material, for example. A gas entry port 320 is through the base plate 310 and is fluidly coupled to a gas source 322. The blocker plate 312 is coupled to the base plate 310 and is disposed interior towards the interior processing region 308 relative to the base plate 310. The blocker plate 312 has passages 324 therethrough. An insulator 318 (e.g., an annular insulator) is disposed between the blocker plate 312 and the gas distribution plate 314. The gas distribution plate 314 (e.g., showerhead) has passages 326 therethrough and is disposed interior towards the interior processing region 308 relative to the blocker plate 312. A pair of insulators 318 (e.g., annular insulators) are disposed between the gas distribution plate 314 and the modulation electrode 316. The modulation electrode 316 is annular and circumscribes the interior processing region 308. An insulator 318 (e.g., an annular insulator) is disposed between the modulation electrode 316 and the chamber body 302, such as when the lid assembly 306 is disposed on the chamber body 302 for processing. The insulators 318 electrically, and in some instances, thermally, isolate respective components between which the respective insulator 318 is disposed. The insulators 318 can be a dielectric material, such as a ceramic or metal oxide, for example, aluminum oxide and/or aluminum nitride.

The lid assembly 306 and/or chamber body 302 can include heating and cooling elements. For example, the base plate 310 can have a conduit for circulating a fluid through the base plate 310. The fluid may be a thermal control fluid, such as a cooling fluid (e.g., water). Further, a heater can be included in the base plate 310, which together with the conduit for circulating a fluid can provide thermal control for the lid assembly 306 to allow temperature uniformity.

Process gases (e.g., one or more precursor and one or more inert carrier gas) may be provided through the gas entry port 320 by the gas source 322 to be introduced into the processing chamber 116. The blocker plate 312 can provide an even gas distribution to a backside of the gas distribution plate 314. The processing gas from the gas entry port 320 enters a first volume 328 partially limited between the base plate 310 and the blocker plate 312, and then flows through the passages 324 through the blocker plate 312 into a second volume 330 between the blocker plate 312 and the gas distribution plate 314. The processing gas then enters the interior processing region 308 from the second volume 330 through the passages 326 through the gas distribution plate 314. The processing gases can be evacuated from the interior processing region 308 by a vacuum pump 342 fluidly coupled to the interior processing region 308 via a valve 344. The vacuum pump 342 may be part of the gas and pressure control system of the processing system 100.

A RF power source 340 is electrically connected to the base plate 310 and is configured to apply a RF potential to the base plate 310 to facilitate the generation of plasma in the interior processing region 308. The RF power source 340 may include a high frequency RF power source (“HFRF power source”) capable of generating an RF power (e.g., at a frequency of about 13.56 MHz), or a low frequency RF power source (“LFRF power source”) generating an RF power (e.g., at a frequency of about 300 kHz). The LFRF power source can provide both low frequency generation and fixed match elements. The HFRF power source can be designed for use with a fixed match and can regulate the power delivered to the load, eliminating concerns about forward and reflected power.

The modulation electrode 316 may be coupled to a tuning circuit 346 that controls an impedance of an electrical path from the modulation electrode 316 to an electrical ground. The tuning circuit 346 comprises an electronic sensor 348 and a variable capacitor 350 that is controllable by the electronic sensor 348. The tuning circuit 346 may be an LC circuit comprising one or more inductors 352. The electronic sensor 348 may be a voltage or current sensor, and may be coupled to the variable capacitor 350 to afford a degree of closed-loop control of plasma conditions inside the interior processing region 308.

The substrate support assembly 354 may be disposed within the processing chamber 116. The substrate support assembly 354 includes a substrate support 358 that may support a substrate 356 during processing. A first electrode 360 and a second electrode 362 are disposed in and/or on the substrate support 358. Further, a heater element 364 is embedded in the substrate support 358. The heater element 364 can be operable to controllably heat the substrate support assembly 354 and the substrate 356 positioned thereon to a target temperature, such as to maintain the substrate 356 at a temperature in a range from about 150° C. to about 1,000° C. The substrate support 358 is coupled to a shaft 366 for support. The shaft 366 can provide a conduit from a gas source 368 and electrical and temperature monitoring leads (not shown) between the substrate support assembly 354 and other components of the processing chamber 116. In some examples, a purge gas may be provided to the backside of the substrate 356 through one or more purge gas inlets 369 connected to the gas source 368. The purge gas flowed toward the backside of the substrate 356 can help prevent particle contamination caused by deposition on the backside of the substrate 356. The purge gas may also be used as a form of temperature control to cool the backside of the substrate 356. Although not illustrated, the shaft 366 may be coupled to an actuator like described above with respect to FIG. 2. The actuator may be flexibly sealed to the chamber body 302 by bellows (not shown) that prevent vacuum leakage from around the shaft 366. The actuator can allow the substrate support 358 to be moved vertically within the chamber body 302 between a process position and a lower, transfer position. The transfer position is slightly below the opening of a slit valve opening formed in a sidewall of the chamber body 302. In operation, the substrate support 358 may be elevated to a position in close proximity to the lid assembly 306, which may further control the temperature of the substrate 356 being processed.

The first electrode 360 may be embedded within the substrate support 358 or coupled to a surface of the substrate support 358. The first electrode 360 may be a plate, a perforated plate, a mesh, a wire screen, or any other distributed arrangement. The first electrode 360 may be a tuning electrode, and may be coupled to a tuning circuit 370. The tuning circuit 370 may have an electronic sensor 372 and a variable capacitor 374 electrically connected between the first electrode 360 and an electrical ground. The electronic sensor 372 may be a voltage or current sensor, and may be coupled to the variable capacitor 374 to provide further control over plasma conditions in the interior processing region 308.

The second electrode 362, which may be a bias electrode, may be coupled to the substrate support 358. The second electrode 362 may be coupled to a bias power source 376 through an impedance matching circuit 378. The bias power source 376 may be DC power, pulsed DC power, RF power, pulsed RF power, or a combination thereof.

The processing chamber 112 also includes a controller (not shown), which may be the system controller 140 or a controller controlled by the system controller 140, for controlling processes within the processing chamber 112.

In operation, a substrate is disposed on the substrate support 358, and process gases are flowed through the lid assembly 306 according to any desired flow plan. A temperature set point is established for the various thermal components in the processing chamber 116. Electric power is coupled to the base plate 310 to establish a plasma in the interior processing region 308. The substrate may be subjected to an electrical bias using the bias power source 376, if desired.

Upon energizing a plasma in the interior processing region 308, a potential difference is established between the plasma and the modulation electrode 316. A potential difference is also established between the plasma and the first electrode 360. The variable capacitors 350 and 374 may then be used to adjust the impedances of the paths to an electrical ground represented by the tuning circuits 346 and 370. A set point may be delivered to the tuning circuit 346 and 370 to provide independent control of the plasma density uniformity from center to edge and deposition rate. The electronic sensors may adjust the variable capacitors to maximize deposition rate and minimize thickness non-uniformity independently. The components implemented to control temperature and uniformity of the plasma, among other, can permit deposition of a highly conformal layer on a substrate being processed, even within small gaps.

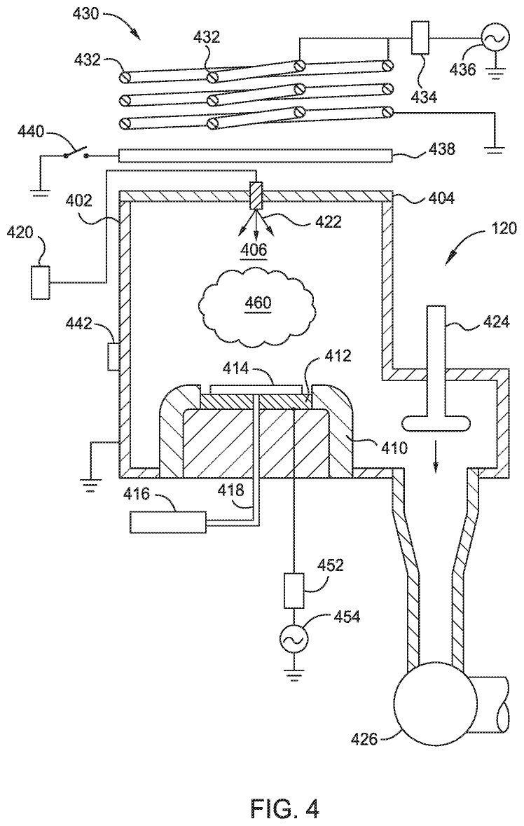

FIG. 4 is a cross-sectional view of the processing chamber 120 that may be used to perform a plasma treatment according to some examples of the present disclosure. The processing chamber 120 is a chamber for the treatment of a substrate, such as a thin film that has been formed on a surface of a substrate, using a plasma. As described herein, the processing chamber 120 is configured to implement an inductively coupled plasma (ICP), although other examples contemplate that the processing chamber 120 is configured to implement other types of plasmas, such as a capacitively coupled plasma (CCP). The processing chamber 112 may be a DPX™ chamber available from Applied Materials of Santa Clara, Calif.

As shown, the processing chamber 120 includes a chamber body 402, a lid assembly 404, and a substrate support assembly 410. The lid assembly 404 is disposed at an upper end of and is supported by the chamber body 402, and the substrate support assembly 410 is at least partially disposed within the chamber body 402. The chamber body 402, lid assembly 404, and substrate support assembly 410 together define an interior processing region 406 within the processing chamber 120 in which a substrate may be processed. The interior processing region 406 may be accessed through a port (not shown) formed in the chamber body 402 that facilitates transfer of a substrate into and out of the processing chamber 120.

The chamber body 402 may be coupled to an electrical ground. The chamber body 402 may include heating and cooling elements embedded therein. For example, liquid-containing conduits (not shown) can run through the chamber body 402, and/or heating elements can be embedded in the chamber body 402 (e.g., heating cartridges or coils) or can be wrapped around the interior process region 406 (e.g., heater wrap or tape). The lid assembly 404 may include or be composed of any suitable dielectric, such as quartz. For some examples, the lid assembly 404 may be various shapes (e.g., dome-shaped). In some examples, the lid assembly 404 may be coated with a ceramic coating, for protection from plasma species.

The substrate support assembly 410 includes a substrate support 412 (e.g., an electrostatic chuck (ESC)). The substrate support 412 is configured to secure a substrate 414 on the substrate support assembly 410 during processing of the substrate 414, such as including exposing the substrate 414 to a plasma in the interior process region 406. In some examples, the substrate support 412 and/or the substrate support assembly 410 includes heating and/or cooling elements configured to control a temperature of the substrate 414 during processing. In some examples, a temperature of the substrate support 412 can be controlled to be in a range from about 20° C. to about 500° C. by use of the heating and cooling elements. The temperature control of the substrate support 412 and substrate 414 via heating and cooling elements embedded within the substrate support assembly 410 can help reduce unwanted temperatures due to ion bombardment, for example.

In some examples, a gas source 416 coupled to the substrate support assembly 410 via a conduit 418 may facilitate heat transfer between the substrate support assembly 410 and the substrate. A gas from the gas source 416 may be provided via the conduit 418 to channels (not shown) formed in the surface of the substrate support assembly 410 under substrate 414 (e.g., a surface of the substrate support 412). The gas may facilitate heat transfer between the substrate support assembly 410 and substrate 414. During processing, the substrate support assembly 410 may be heated to a steady state temperature, and then the gas may facilitate uniform heating of the substrate 414. The substrate support assembly 410 may be heated by a heating element (not shown), such as a resistive heater embedded within substrate support assembly 410 or a lamp generally aimed at substrate support assembly 410 or substrate 414 when thereon.

The processing chamber 120 includes a gas source 420, one or more gas entry ports 422, a valve 424 (e.g., a throttle valve), and a vacuum pump 426. The gas source 420, valve 424, and vacuum pump 426, individually and/or collectively, may be part of the gas and pressure control system of the processing system 100. One or more process gases may be supplied from the gas source 420 through the one or more gas entry ports 422 to supply the gas(es) in the interior process region 406 for generating a plasma. The valve 424 is configured to permit gas(es) to be maintained or evacuated from the interior process region 406. The vacuum pump 426 is configured to evacuate or exhaust gas(es) from the interior process region 406, e.g., when the valve 424 is open. The gas source 420, valve 424, and vacuum pump 426 can be configured to collectively maintain a target pressure within the interior process region 406.

The processing chamber 120 includes a plasma generator 430. The plasma generator 430 includes an inductive coil element 432, a first impedance matching network 434, a RF power source 436, a shielding electrode 438, a switch 440, and a detector 442. As illustrated, a RF antenna including at least one inductive coil element 432 is disposed on the lid assembly 404. In some examples, such as shown in FIG. 4, two coaxial coil elements, which are disposed about a central axis of the interior process region 406 of the processing chamber 120, are electrically connected between the first impedance matching network 434 and an electrical ground, and the first impedance matching network 434 is electrically connected to the RF power source 436. The inductive coil element(s) 432 can be driven at an RF frequency, e.g., by the RF power source 436, to generate a plasma in the interior process region 406 of the processing chamber 120. In some examples, one or more inductive coil elements 432 may be disposed around at least a portion of chamber body 402. The RF power source 436 may be capable of producing an RF power, e.g., up to 4 kW at a frequency of 13.56 MHz in some examples. The RF power supplied to inductive coil elements 432 may be pulsed or power cycled at a frequency up to 100 kHz, for example.

The shielding electrode 438 is interposed between inductive coil elements 432 of the RF antenna and the lid assembly 404, as illustrated, although, the shielding electrode 438 may be omitted in some examples. The shielding electrode 438 may be selectively (e.g., alternately) electrically floating or coupled to an electrical ground via any suitable mechanism for making and breaking an electrical connection, such as the switch 440.

In some examples, the detector 442 may be attached to the chamber body 402 to facilitate determining when gas(es) within interior process region 406 has been energized into a plasma. The detector 442 may, for example, detect the radiation emitted by the excited gas(es) or use optical emission spectroscopy (OES) to measure the intensity of one or more wavelengths of light associated with the generated plasma.

The processing chamber 120 also includes a second impedance matching network 452 and biasing power source 454. The substrate support assembly 410 may be coupled, through the second impedance matching network 452, to the biasing power source 454. The biasing power source 454 may be capable of producing an RF signal having a drive frequency that is in a range from 1 MHz to 160 MHz and a power in a range from about 0 kW to about 3 kW, similar to the RF power source 436. The biasing power source 454 may be capable of producing a power in a range from about 1 W to about 1 kW at a frequency in a range from 2 MHz to 160 MHz, such as with a frequency of 13.56 MHz or 2 MHz. In some examples, biasing power source 454 may be a DC or pulsed DC source. In some examples, an electrode that is coupled to the biasing power source 454 is disposed within the substrate support 412. The biasing power source 454 can provide a substrate voltage bias across the substrate 414 to facilitate the treatment of the substrate 414.

The processing chamber 120 also includes a controller (not shown), which may be the system controller 140 or a controller controlled by the system controller 140, for controlling processes within the processing chamber 120.

In operation, the substrate 414 may be placed on the substrate support 412, and one or more process gases may be supplied from the gas source 420 through one or more gas entry ports 422 into the interior process region 406 of the processing chamber 120. The one or more gases supplied into the interior process region 406 may be energized into a plasma 460 in interior process region 406 by the plasma generator 430 (e.g., by suppling a power from the RF power source 436). The biasing power source 454 may provide a voltage bias across the substrate 414 (e.g., by supplying a voltage from the biasing power source 454) to facilitate the plasma process. The pressure within the interior process region 406 and temperature of the substrate 414 may be controlled to a target pressure and a target temperature. The plasma 460 may bombard the substrate 414, e.g., to alter the properties of a film on the substrate 414.

The plasma density of the plasma 460 can be measured by use of any plasma diagnostics technique, such as by use of Self Excited Electron Plasma Resonance Spectroscopy (SEERS), a Langmuir probe, or other suitable technique. An inductive coil element 432 configuration, such as illustrated in FIG. 4, can provide improved control and generation of a high density plasma versus other plasma source configurations, such as a capacitively coupled plasma.

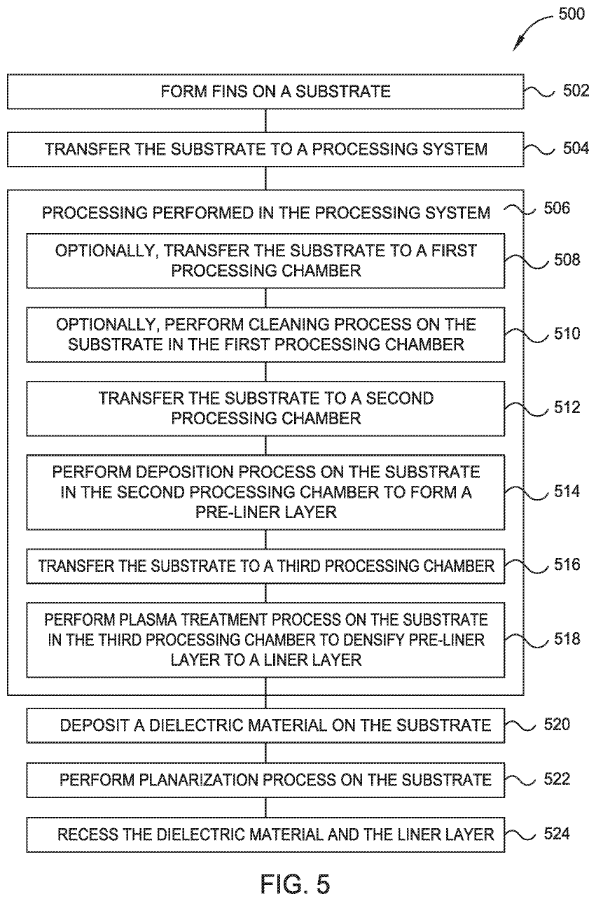

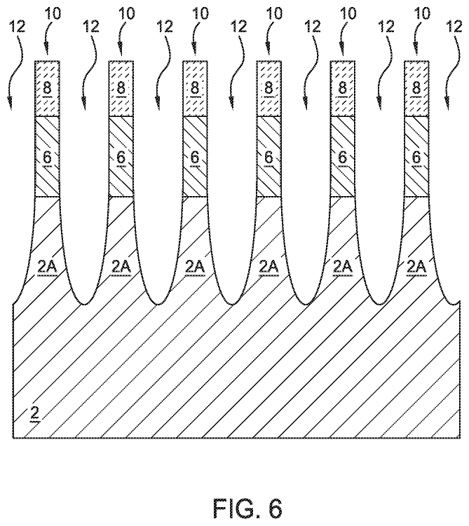

FIG. 5 is a flowchart of a method 500 of semiconductor processing according to some examples of the present disclosure. FIGS. 6 through 10 are cross-sectional views of intermediate semiconductor structures illustrating aspects of the method 500 of FIG. 5 according to some examples of the present disclosure. Examples described herein are in the context of forming isolation structures (e.g., shallow trench isolations (STIs)) between fins on a substrate. A person having ordinary skill in the art will readily understand various applications of aspects described herein to other contexts, and such variations are contemplated within the scope of other examples.

According to block 502 of FIG. 5, fins 10 are formed on a substrate 2. FIG. 6 illustrates a cross-sectional view of fins 10 formed on a substrate 2. To obtain the structure of FIG. 6, a substrate 2 is provided. The substrate 2 can be any appropriate semiconductor substrate, such as a bulk substrate, semiconductor-on-insulator (SOI) substrate, or the like. In some examples, the substrate 2 is a bulk silicon wafer. Examples of substrate sizes include 200 mm diameter, 350 mm diameter, 400 mm diameter, and 450 mm diameter, among others. An epitaxial layer 6 (e.g., a heteroepitaxial layer) is formed on the substrate 2. In some examples, the material of the epitaxial layer 6 is silicon germanium. The epitaxial layer 6 can be formed using any appropriate epitaxial growth process.

Fins 10 are then formed on the substrate 2. The fins 10 can be formed by etching features, such as trenches 12 that extend into the substrate 2 such that each fin 10 is defined between a neighboring pair of features (e.g., trenches 12). As illustrated, mask portions 8 are formed on the epitaxial layer 6 and are used to mask the etching that forms the trenches 12. For example, the mask portions 8 can be or include a nitride, such as silicon nitride, silicon carbon nitride, silicon oxynitride, etc. A layer of the mask portions 8 can be deposited on the epitaxial layer 6 and patterned into the mask portions 8 for the etch process using an appropriate patterning process. The patterning process can include a multiple patterning process, such as self-aligned double patterning (SADP), lithography-etch-lithography-etch (LELE) double patterning, etc., to achieve a target pitch between fins 10. An example etch process to etch the trenches 12 includes a reactive ion etch (RIE) process or the like. As illustrated in FIG. 6, each fin 10 includes a portion of the epitaxial layer 6, and a portion 2A of the substrate 2, with a mask portion 8 thereon.

According to block 504, the substrate 2 having the fins 10 formed thereon is then transferred to a processing system, such as the processing system 100 of FIG. 1. For example, the substrate 2 is transferred by a front opening unified pod (FOUP) to a factory interface, and at the factory interface, the substrate 2 is transferred from the FOUP to a load lock chamber 104 or 106 through a port. The load lock chamber 104 or 106 is then pumped down as described above. Subsequent transfers and processing are performed in the processing system 100, as shown by block 506, e.g., without exposing the substrate 2 to an atmospheric ambient environment outside of the processing system 100 and without breaking a low pressure or vacuum environment maintained within the transfer apparatus of the processing system 100. The processing illustrated in block 506 is merely an example. Some processes in block 506 may not be performed in the processing system 100, and/or additional process may be performed in the processing system 100.

In block 508, optionally, the substrate 2 is transferred to a first processing chamber, e.g., processing chamber 112, of the processing system 100. For example, the transfer robot 110 transfers the substrate 2 from the load lock chamber 104 or 106 through a port and to the processing chamber 112 through a port. In block 510, optionally, a cleaning process is performed on the substrate 2 in the processing chamber 112. The cleaning process can be the SiCoNi® Preclean process. The cleaning process can remove any native oxide formed on the fins 10 as a result of exposure to an atmospheric ambient environment during transport of the substrate 2 to the processing system 100.

In some examples performed with the processing chamber 112 illustrated in FIG. 2, the cleaning process includes flowing a mixture of nitrogen trifluoride (NF₃) and helium (He) from gas entry port 226, and flowing ammonia (NH₃) from gas entry port 225. The mixture of nitrogen trifluoride (NF₃) and helium (He) can be in a ratio in a range from 1:350 (NF₃:He) to 1:120 (NF₃:He), which mixture can be flowed from gas entry port 226 at a flow rate in a range from 5000 sccm to 7000 sccm, such as with a flow rate of trifluoride (NF₃) in a range from 10 sccm to 25 sccm, and a flow rate of helium (He) in a range from about 3000 sccm to 3500 sccm. A pressure in the chamber 122 during the cleaning process can be maintained in a range from 0.25 Torr to about 2 Torr. A power applied by the RF power source 224 can be in a range from about 10 W to about 50 W at a frequency in a range from about 10 MHz to about 20 MHz (e.g., 13.56 MHz).

After the cleaning process is performed in the processing chamber 112, in block 512, the substrate 2 is transferred to a second processing chamber, e.g., processing chamber 116, of the processing system 100. For example, the substrate 2 is transferred by the transfer robot 110 from the processing chamber 112 through a port and to the processing chamber 116 through another port.

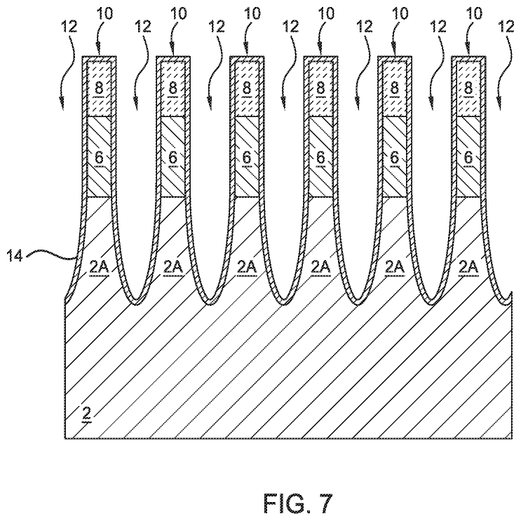

In block 514, a deposition process is performed on the substrate 2 in the processing chamber 116 to form a pre-liner layer 14. FIG. 7 illustrates the formation of a pre-liner layer 14. The pre-liner layer 14 is conformally formed in the trenches 12 and on the fins 10. In some examples, the pre-liner layer 14 is conformally deposited, such as by PECVD, ALD, or the like, in the trenches 12 and on the fins 10. In some examples, the pre-liner layer 14 is or includes amorphous silicon, although in other examples, the pre-liner layer 14 can be or include any material that is capable of being densified to form a hermetic barrier. In some examples, a thickness of the pre-liner layer 14 is in a range from about 1 nm to about 4 nm, such as about 1.5 nm to about 2.5 nm, such as about 2 nm. The pre-liner layer 14 can have a good step coverage along the fins 10 and trenches 12. The processing chamber 116 can be the Precision® chamber, which can perform the deposition process, such as illustrated in FIG. 3.

In some examples performed with the processing chamber 116 illustrated in FIG. 3, the deposition process deposits the pre-liner layer 14 of amorphous silicon. In such examples, a silicon-containing precursor gas can be supplied from the gas source 322. Example precursor gases include disilane (Si₂H₆), trisilane (Si₃H₆), and/or other silicon-containing precursors. A flow rate of the precursor gas can be in a range from about 10 sccm to about 2000 sccm. The precursor gas can be mixed with an inert carrier gas, such as argon (Ar), helium (He), hydrogen (H₂), nitrogen (N₂), or the like. A pressure within the interior processing region 308 during the deposition process can be maintained at a large pressure, such as up to and including 600 Torr. A processing temperature during the deposition process can be in a range from about 100° C. to about 500° C. The processing chamber 116 may permit depositing the pre-liner layer 14 at a high pressure and low temperature equal to or less than 550° C. (with a high temperature uniformity), which can permit the deposition of a highly conformal layer in small scaled gaps, such as in the trenches 12.

After the deposition process is performed in the processing chamber 116, in block 516, the substrate 2 is transferred to a third processing chamber, e.g., processing chamber 120, of the processing system 100. For example, the substrate 2 is transferred by the transfer robot 110 from the processing chamber 116 through the port and to the processing chamber 120 through another port.

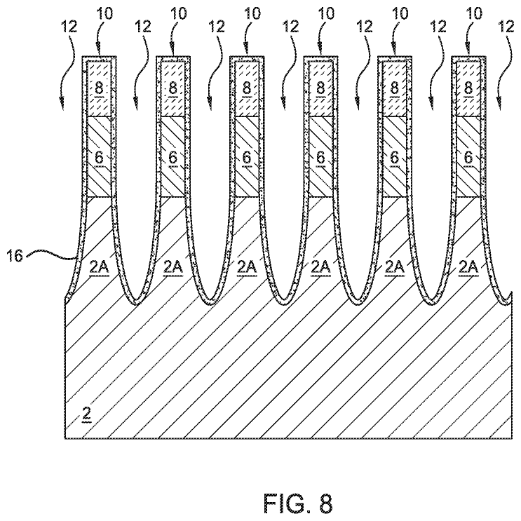

In block 518, a plasma treatment process is performed on the substrate 2 in the processing chamber 120 to densify the pre-liner layer 14 to form a liner layer 16. FIG. 8 illustrates the densification of the pre-liner layer 14 to form a liner layer 16. The pre-liner layer 14 can be densified using a plasma process to form the liner layer 16. In some examples, a helium and/or nitrogen-containing plasma is implemented. The pre-liner layer 14 can be exposed to the helium and/or nitrogen-containing plasma, which densifies the pre-liner layer 14, and in some cases causes nitrogen to diffuse into and/or react with the pre-liner layer 14 to form the liner layer 16. Thus, in some examples, the plasma process can therefore nitride the pre-liner layer 14 to form the liner layer 16. In examples where the pre-liner layer 14 is amorphous silicon and is subsequently densified using a nitrogen-containing plasma, the liner layer 16 can be a nitrogen-containing silicon layer (e.g., a “nitride-like” layer) and/or a silicon nitride layer. The liner layer 16 can form a hermetic barrier on the fins 10 to reduce and/or prevent oxygen from diffusing through the liner layer 16 to the fins 10 during subsequent processing. The processing chamber 120 can be the DPX™ chamber, which can perform the plasma process, such as illustrated in FIG. 4.

In some examples performed with the processing chamber 120 illustrated in FIG. 4, a pre-liner layer 14 of amorphous silicon is densified and nitrided by a plasma process to form a liner layer 16 of a nitride-like layer or silicon nitride. In such examples, the plasma process can include generating a nitrogen-containing plasma by flowing a nitrogen-containing process gas, which can include an inert carrier gas, from the gas source 420 through the gas entry port 422. The nitrogen-containing process gas, in some examples, is or includes a mixture of nitrogen (N₂) and argon (Ar) or helium (He). A pressure in the interior processing region 406 during the plasma process can be in a range from about 1 mTorr to about 100 mTorr. A power of the RF power source 436 during the plasma process can be in a range from about 500 W to about 5000 W at a frequency in a range from about 2 MHz to about 160 MHz (e.g., 13.56 MHz). In some examples, the power of the RF power source can be pulsed. The bias power source 454 can be turned off or can apply no power to the substrate support. The bias power source 454 can be in a range from about 0 W to about 2000 W at a frequency in a range from about 2 MHz to about 160 MHz (e.g., 13.56 MHz). A temperature of the substrate support 412 during the plasma process can be in a range from about 150° C. to about 500° C., such as about 450° C. In some examples of the plasma process, the substrate temperature is held at about 350° C. to 500° C., an RF power of about 2000-2500 W is provided to the process gas, a substrate RF bias power of about 0-1000 W (e.g., 1 to 100 W) is applied, the chamber is held at about 5-20 mTorr, and nitrogen and helium are flowed for a period of about 4 min.

Referring back to block 514, in some examples, the liner layer 16 is formed without using a chlorine-containing gas. By avoiding using a chlorine-containing gas, dangerous and corrosive byproduct gases, such as hydrochloric acid (HCl) and chlorine (Cl₂) are not formed. Hence, safety and environmental advantages can be achieved. Therefore, as described above for some examples, the deposition of the pre-liner layer 14 can implement a silicon-containing precursor and an inert carrier gas, neither of which contains chlorine, and the densification of the pre-liner layer 14 to form the liner layer 16 can implement a nitrogen-containing plasma that can include an inert carrier gas, neither of which contains chlorine.

Transferring the substrate 2 within the single processing system 100 permits transfer of the substrate 2 without exposing the substrate 2 to an atmospheric ambient environment exterior to the processing system 100 (e.g., the fab environment). By avoiding exposure of the substrate 2 to such atmospheric ambient environment, a cleaning process between the processing in the processing chamber 116 and the processing in the processing chamber 120 can be avoided, such as a result of no oxidation or contamination occurring due to exposure to such atmospheric ambient environment.

By forming a liner layer 16 as described, the liner layer 16 can be a highly hermetic layer. By being a highly hermetic layer, little to no oxygen may diffuse or penetrate through the liner layer 16 to the fins 10. Hence, sides of the fins 10 can have reduced or no oxidation relative to other liner layers that can be formed as part of an isolation structure. With reduced or no oxidation of the fins 10, widths (e.g., a critical dimension (CD)) of the fins 10 can be more easily maintained during subsequent processing. For example, if the sides of the fins 10 become significantly oxidized, the etching of a subsequently deposited dielectric material to recess that material (as described below) can cause the oxidized sides of the fins 10 to also be etched, which causes loss to widths of the fins 10. Without oxidation or with little oxidation, no or little oxide will be etched such that no or little loss to the widths of the fins 10 can occur. The highly hermetic layer can permit the substrate 2 to be subsequently exposed to, e.g., an atmospheric ambient environment without significant oxidation occurring, and can permit freedom in subsequent processing that might otherwise cause significant oxidation.

After the plasma treatment process in the processing chamber 120, the substrate 2 can be transferred by the transfer robot 110 from the processing chamber 120 through the port to another processing chamber through a port (e.g., for deposition of subsequent materials) and/or then is transferred to a load lock chamber 104 or 106 through a port. The substrate 2 is then transferred out of the load lock chamber 104 or 106 through a port via the factory interface to a FOUP. The substrate 2 can then be transported to other processing systems to undergo further processing.

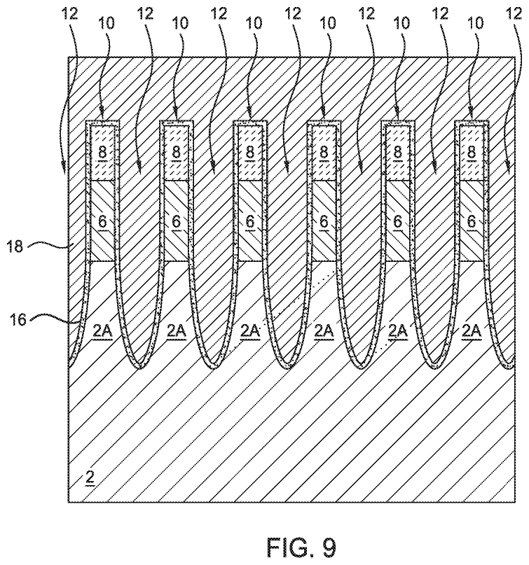

In block 520, a dielectric material 18 is deposited on the substrate 2. FIG. 9 illustrates the formation of a dielectric material 18 on the liner layer 16. In some examples, the dielectric material 18 is flowed on the liner layer 16, into the trenches 12, and on the fins 10 as one material and converted to another material. As an example, a nitrogen-containing material is flowed and subsequently converted to an oxide material to form the dielectric material 18. The formation of the dielectric material 18 may be by a flowable CVD (FCVD). A conversion process of the FCVD can include, for example, exposing the flowed material to a steam in a high pressure environment. The high pressure environment can be up to and including a pressure of 80 Bar (e.g., approximately 60,000 Torr), such as in a range from 1 Bar to 80 Bar. Due to the presence of the liner layer 16 that is highly hermetic, the conversion in a high pressure environment may be performed with little to no risk of oxidizing the fins 10, as stated above.

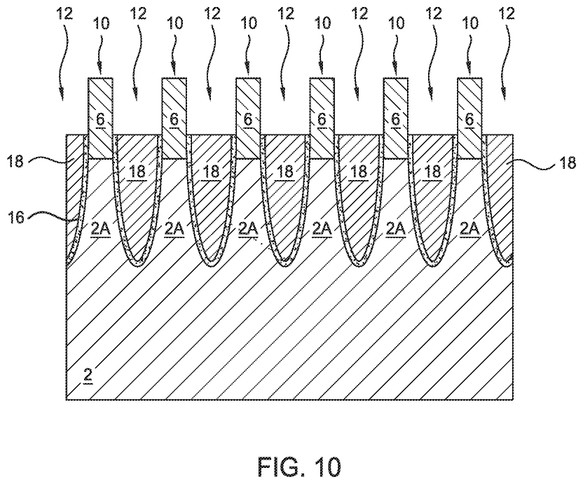

FIG. 10 illustrates the recessing of the dielectric material 18 and liner layer 16 to form isolation structures (e.g., STIs) in the trenches 12 between the fins 10. In block 522, a planarization process, such as a chemical mechanical planarization (CMP), is performed to planarize top surfaces of the dielectric material 18 and liner layer 16 with top surfaces of the epitaxial layers 6 of the fins 10 (not shown). The planarization process can therefore remove the mask portions 8. In block 524, the dielectric material 18 and liner layer 16 are recessed, as shown in FIG. 10. One or more etch processes can be performed to recess the dielectric material 18 and liner layer 16 such that the fins 10 protrude from between neighboring isolation structures. Top surfaces of the isolation structures (e.g., top surface of the dielectric material 18 and liner layer 16) can be recessed to varying depths from top surfaces of the fins 10, and the illustration of FIG. 10 is merely an example. As stated above, the liner layer 16 is hermetic such that the fins 10 are not significantly oxidized, which can reduce loss of widths of the fins 10 during the recessing of the dielectric material 18 and liner layer 16.

The fins 10, with the isolation structures therebetween, can thereafter be used to form any appropriate device structure. For example, the fins 10 can be used to form FinFETs. A gate structure can be formed on and longitudinally perpendicularly to a fin 10. The gate structure can include a gate dielectric (e.g., a high-k gate dielectric) along surfaces of the fin, one or more work-function tuning layers on the gate dielectric, and a metal fill on the work-function tuning layer(s). The gate structure can define a channel region in the respective fin 10 underlying the gate structure. Source/drain regions (e.g., epitaxial source/drain regions) can be formed in the fin on opposing sides of the channel region. The gate structure, channel region, and source/drain regions together can form a FinFET.

In examples described herein, an isolation structure between fins can be formed, where a dimension between the fins is reduced. A highly conformal, hermetic liner layer with a small thickness can be formed between fins. The liner layer can reduce oxidation of fins, which can reduce loss of widths of fins and increase flexibility in subsequent processing. The isolation structures can be formed using low temperature processing, which can reduce stress and bending in fins. Further, the liner layer can be formed without using a chlorine-containing gas, which can reduce safety and environmental concerns. Additionally, the formation of the liner layer can be performed in the single processing system 100, which permits transfer of the substrate 2 between different chambers for different processing without exposing the substrate 2 to an atmospheric ambient environment exterior to the processing system 100 (e.g., the fab environment). By avoiding exposure of the substrate to such atmospheric ambient environment, cleaning processes between the different processing can be avoided, such as a result of no oxidation and no contamination occurring due to exposure to such atmospheric ambient environment. Accordingly, examples described herein provide for an integrated solution to the formation of the liner layer.

While the foregoing is directed to various examples of the present disclosure, other and further examples may be devised without departing from the basic scope thereof, and the scope thereof is determined by the claims that follow.

1. A method for semiconductor processing, the method comprising:
forming fins on a substrate;
forming a liner layer conformally on and between the fins, forming the liner layer comprising:
conformally depositing a pre-liner layer on and between the fins; and
densifying, using a plasma treatment, the pre-liner layer to form the liner layer; and
forming a dielectric material on the liner layer and between the fins.

2. The method of claim 1, wherein:
forming the liner layer is performed in a single processing system;
conformally depositing the pre-liner layer is performed in a first processing chamber of the single processing system;
densifying the pre-liner layer is performed in a second processing chamber of the single processing system; and
the substrate is transferred from the first processing chamber to the second processing chamber through a transfer apparatus of the single processing system.

3. The method of claim 2, wherein the substrate is transferred from the first processing chamber to the second processing chamber without exposing the substrate to an atmospheric ambient environment.

4. The method of claim 2, wherein the substrate is transferred from the first processing chamber to the second processing chamber in a transfer environment in the transfer apparatus with a pressure less than or equal to 300 Torr without removing the transfer environment during the transferring.

5. The method of claim 1, wherein forming the liner layer does not include using a chlorine-containing gas.

6. The method of claim 1, wherein forming the dielectric material comprises:
flowing a flowable material; and
converting the flowable material to the dielectric material, converting comprising exposing the flowable material to an environment having pressure in a range from 1 Bar to 80 Bar.

7. The method of claim 1, wherein the pre-liner layer is a layer of silicon, and the liner layer is nitrided silicon.

8. The method of claim 1 further comprising recessing the dielectric material and the liner layer, wherein after recessing, the fins protrude above top surfaces of the dielectric material and the liner layer.

9. A semiconductor processing system comprising:
a transfer apparatus;
a first processing chamber coupled to the transfer apparatus;
a second processing chamber coupled to the transfer apparatus; and
a system controller configured to:
control a deposition process performed in the first processing chamber, the deposition process conformally depositing a pre-liner layer on and between fins on a substrate;
control a transfer of the substrate from the first processing chamber to the second processing chamber through the transfer apparatus; and
control a plasma treatment process performed in the second processing chamber, the plasma treatment process densifying the pre-liner layer to form a liner layer.

10. The semiconductor processing system of claim 9 further comprising a third processing chamber coupled to the transfer apparatus, wherein the system controller is configured to:
control a cleaning process performed in the third processing chamber, the cleaning process cleaning the substrate; and
control a transfer of the substrate from the third processing chamber to the first processing chamber through the transfer apparatus.

11. The semiconductor processing system of claim 9, wherein the system controller is configured to cause the transfer of the substrate from the first processing chamber to the second processing chamber through a vacuum environment.

12. The semiconductor processing system of claim 9, wherein the system controller is configured to maintain a pressure in the transfer apparatus less than or equal to 300 Torr during the transfer of the substrate from the first processing chamber to the second processing chamber.

13. The semiconductor processing system of claim 9, wherein the deposition process and the plasma treatment process do not include using a chlorine-containing gas.

14. The semiconductor processing system of claim 9, wherein:
the deposition process comprises flowing a silicon-containing precursor gas, the pre-liner layer being a layer of silicon; and
the plasma treatment process comprises flowing a nitrogen-containing gas, the liner layer being a layer of nitrided silicon.

15. A semiconductor processing system, comprising:
a non-transitory computer-readable medium storing instructions that, when executed by a processor, cause a computer system to perform operations of:
controlling a deposition process in a first processing chamber of a processing system, the deposition process conformally depositing a pre-liner layer on and between fins on a substrate;
controlling a transfer of the substrate from the first processing chamber to a second processing chamber of the processing system through a transfer apparatus of the processing system, the first processing chamber and the second processing chamber being coupled to the transfer apparatus; and
controlling a plasma treatment process in the second processing chamber, the plasma treatment process densifying the pre-liner layer to form a liner layer.

16. The semiconductor processing system of claim 15, wherein controlling the transfer of the substrate from the first processing chamber to the second processing chamber is performed without exposing the substrate to an ambient environment exterior to the processing system.

17. The semiconductor processing system of claim 15, wherein controlling the transfer of the substrate from the first processing chamber to the second processing chamber includes controlling the transfer of the substrate in a transfer environment with a pressure less than or equal to 300 Torr in the transfer apparatus.

18. The semiconductor processing system of claim 15, wherein the instructions, when executed by the processor, do not cause the computer system to implement a cleaning process after the deposition process and before the plasma treatment process.

19. The semiconductor processing system of claim 15, wherein the deposition process and the plasma treatment process do not include using a chlorine-containing gas.

20. The semiconductor processing system of claim 15, wherein:
the deposition process comprises flowing a silicon-containing precursor gas, the pre-liner layer being a layer of silicon; and
the plasma treatment process comprises flowing a nitrogen-containing gas, the liner layer being a layer of nitrided silicon.
